(19) United States
(12) Patent Application Publication
(10) Pub. No.: US 2012/0124830 A1
(43) Pub. Date: May 24, 2012

(54) PROCESS FOR FABRICATING CIRCUIT BOARD

(75) Inventors: David C. H. Cheng, Taoyuan County (TW); Shao-Chien Lee, Taoyuan County (TW); Tzyy-Jang Tseng, Hsinchu (TW)

(73) Assignee: UNIMICRON TECHNOLOGY CORP., Taoyuan (TW)

(21) Appl. No.: 13/362,958

(22) Filed: Jan. 31, 2012

Related U.S. Application Data
(62) Division of application No. 12/047,936, filed on Mar. 13, 2008.

(30) Foreign Application Priority Data
Dec. 11, 2007 (TW) 96147213

(51) Int. Cl. H05K 3/10

(52) U.S. Cl. 29/846

(57) ABSTRACT

A process for fabricating a circuit board is provided. In the process, first, a circuit substrate including an insulation layer and at least a pad contacting the insulation layer is provided. Next, a barrier material layer is formed on the circuit substrate. The barrier material layer completely covers the insulation layer and the pad. Then, at least one conductive bump is formed on the barrier material layer. The conductive bump is opposite to the pad, and the material of the barrier material layer is different from the material of the conductive bump. Next, a portion of the barrier material layer is removed by using the conductive bump as a mask, so as to expose the surface of the insulation layer and to form a barrier connected between the conductive bump and the pad.

### CROSS-REFERENCE TO RELATED APPLICATION

This application is a Divisional of and claims the priority benefit of U.S. patent application Ser. No. 12/047,936, filed on Mar. 13, 2008, now pending, which claims the priority benefits of Taiwan application Serial No. 96147213, filed Dec. 11, 2007. The entirety of each of the above-mentioned patent applications is hereby incorporated by reference herein and made a part of this specification.

### BACKGROUND OF THE INVENTION

1. Field of the Invention

The present invention relates to a circuit board, and in particular, to a circuit board with a conductive bump and a process for fabricating the circuit board with the conductive bump.

2. Description of Related Art

Many home appliances and electronic apparatuses need to be equipped with electronic components such as resistors, capacitors, inductors, chips, chip packages, and etc.; however, these electronic components can operate only after they are installed to a circuit board.

FIG. 1 illustrates a schematic cross-sectional view of a conventional circuit board. Referring to FIG. 1, the circuit board 100 usually has a copper circuit layer 110, a solder mask layer 120 and a plurality of solder bumps 130, wherein the copper circuit layer 110 includes a plurality of pads 112 (FIG. 1 merely illustrates a pad 112 and a solder bump 130) and a plurality of traces 114, and the solder mask layer 120 covering the copper circuit layer 110 with an opening H1 exposing a portion of the pads 112.

The material of the solder bump 130 is usually soldering tin, and the solder bumps 130 are respectively disposed in the openings H1 and connected to the pads 112. The solder bumps 130 can be connected with the above-mentioned electronic components, so that the electronic components can be installed onto the circuit board 100. Thereby, the electronic components can operate.

However, the conventional circuit board 100 has a long-existing problem. In detail, due to the material property of the solder bump 130, the solder bump 130 cannot completely cover the whole surface of the pad 112. Namely, the solder bump 130 merely contact a portion of the surface of the pad 112. As a result, the contact area between the solder bump 130 and the pad 112 is limited, so that the adhesion therebetween is not sufficient. Therefore, the solder bump 130 peels off from the pad 112 easily, and the product reliability of the circuit board 100 is reduced.

### SUMMARY OF THE INVENTION

The present invention is directed to a process for fabricating a circuit board, which can improve the adhesion between solder bumps and the circuit board.

The present invention is directed to a circuit board having stronger adhesion to solder bumps.

The present invention provides a process for fabricating a circuit board. First, a circuit substrate is provided. The circuit substrate includes an insulation layer and at least one pad in contact with the insulation layer. Then, a barrier material layer is formed on the circuit substrate, wherein the barrier material layer completely covers a surface of the insulation layer and the pad. Next, at least one conductive bump is formed on the barrier material layer, wherein the conductive bump is opposite to the pad, and the material of the barrier material layer is different from the material of the conductive bump. Then, a portion of the barrier material layer is removed by using the conductive bump as a mask, so as to expose the surface of the insulation layer and to form a barrier connected between the conductive bump and the pad.

The present invention further provides a circuit board comprising a circuit substrate, at least one conductive bump and at least one barrier. The circuit substrate includes an insulation layer and at least one pad, wherein the pad is in contact with the insulation layer. The conductive bump is disposed upon the pad, wherein the conductive bump has a bottom surface opposite to the pad. The barrier is connected between the conductive bump and the pad, wherein the barrier completely covers the bottom surface, and an edge of the barrier is substantially aligned with an edge of the bottom surface. The material of the barrier is different from the material of the conductive bump.

In light of the above, the present invention can enhance the adhesion between the solder bumps and the circuit board, and thereby it is less likely for the solder bumps to peel off from the circuit board. As a result, the invention can make an electronic component installed onto the circuit board more firmly, so as to improve the product reliability of the circuit board.

In order to make the aforementioned features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a schematic cross-sectional view of a conventional circuit board.

FIG. 2A is a schematic cross-sectional view of a circuit board according to an embodiment of the present invention.

FIG. 2B is a schematic cross-sectional view illustrating a plurality of solder bumps connected with the circuit board of FIG. 2A.

FIGS. 3A to 3F are schematic views illustrating a process for fabricating the circuit board of FIG. 2A.

FIG. 4A is a schematic cross-sectional view of a circuit board according to another embodiment of the present invention.

FIG. 4B is a schematic cross-sectional view illustrating a plurality of solder bumps connected with the circuit board of FIG. 4A.

FIGS. 5A to 5F are schematic views illustrating a process for fabricating the circuit board of FIG. 4A.

### DESCRIPTION OF EMBODIMENTS

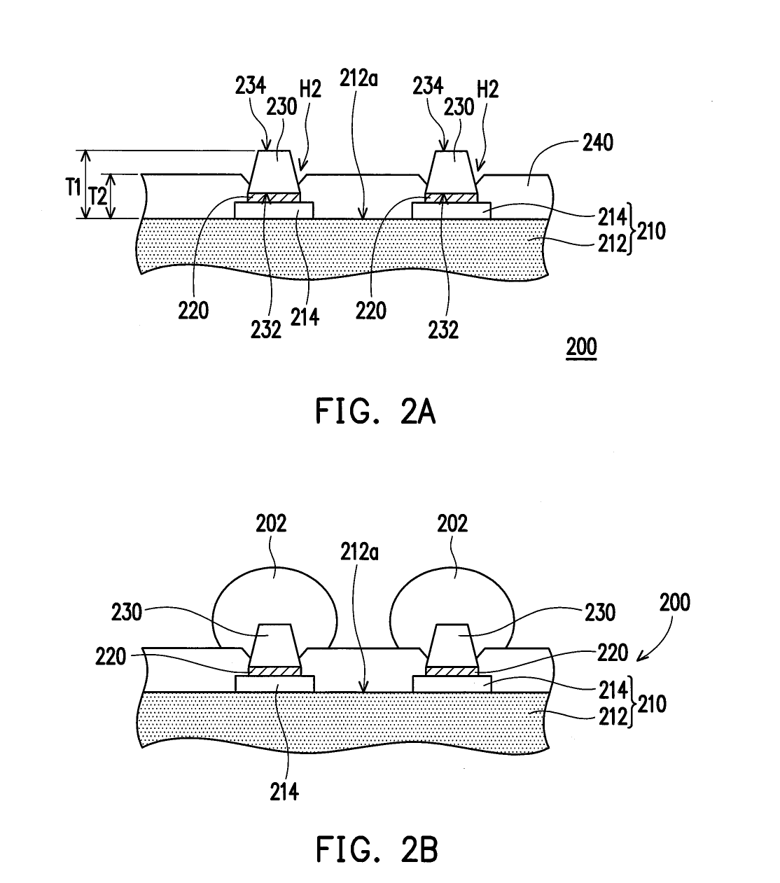

FIG. 2A is a schematic cross-sectional view of a circuit board according to an embodiment of the present invention. Referring to FIG. 2A, a circuit board 200 includes a circuit substrate 210, a plurality of barriers 220 and a plurality of conductive bumps 230. The circuit substrate 210 includes an insulation layer 212 and a plurality of pads 214. The pads 214 are in contact with the insulation layer 212. The pads 214 are located on the surface 212a of the insulation layer 212 and protrude from the surface 212a.

The circuit substrate 210 further includes a plurality of traces disposed on the surface 212a (not shown in FIG. 2A), and the circuit substrate 210 may further include a plurality of conductive blind vias, a plurality of plated through holes or other inner circuit structures (not shown in FIG. 2A). Therefore, the circuit substrate 210 is substantially a circuit board, and the circuit substrate 210 is, for example, a single side circuit board, a double side circuit board or a multi-layer circuit board.

Accordingly, the insulation layer 212 can be fabricated by using a prepreg, a resin material, a ceramic material or a flexible material, wherein the flexible material includes polyimide (PI), polyester (PE), polyurethane (PU), polyethylene terephthalate (PET), or other flexible macromolecule materials. When the insulation layer 212 is fabricated by using the prepreg, the resin material or the ceramic material, the circuit substrate 210 is substantially a rigid circuit board. When the insulation layer 212 is fabricated by using the flexible material, the circuit substrate 210 is substantially a flexible circuit board.

The conductive bumps 230 are disposed upon the pads 214, while the barriers 220 are connected between the pads 214 and the conductive bumps 230. Each of the conductive bumps 230 has a bottom surface 232 and a top surface 234 opposite thereto; wherein the bottom surfaces 232 of the conductive bumps 230 are opposite to the pads 214, and the barriers 220 completely cover the bottom surfaces 232 of the conductive bumps 230.

In one conductive bump 230, the area of the top surface 234 may be smaller than the area of the bottom surface 232, and the conductive bump 230 can taper from the bottom surface 232 to the top surface 234, as shown in FIG. 2A. Certainly, in other embodiments not illustrated, according to different demands for products, the top surface 234 and the bottom surface 232 can have the same area or even the same shape. Namely, the conductive bumps 230 can be a pillar. In other embodiments, the conductive bumps 230 can be in a cone shape or other suitable shapes.

The material of the barrier 220 is different from the material of the conductive bump 230. The material of the barrier 220 can be tin, gold, nickel, chromium, zinc, aluminum, titanium, any other suitable material, or a combination thereof. In other words, the material of the barrier 220 can be alloy, or the barrier 220 can be a multilayer film formed by at least two different metals.

The material of the conductive bumps 230 can be copper, silver, carbon, or any other suitable conductive material. When the material of the conductive bumps 230 is carbon, the conductive bump 230 can be fabricated by using graphite, conductive carbon fiber, or other conductive carbon materials. Furthermore, the material of the conductive bumps 230 can be different from the material of the pad 214. Of course, according to different demands for products, the material of the conductive bumps 230 can be the same as that of the pads 214. For example, the material of the conductive bumps 230 and the material of the pads 214 are copper.

The circuit board 200 can further include a passivation layer 240 disposed on the insulation layer 212. The passivation layer 240 has a plurality of openings H2 exposing the conductive bumps 230. The total thickness T1 of the conductive bump 230, the pad 214 and the barrier 220 is larger than the thickness T2 of the passivation layer 240. In other words, the conductive bumps 230 protrude from the surface of the passivation layer 240.

The passivation layer 240 can be formed by a solder resist lacquer, a dry film, a cover layer or other suitable insulation materials, wherein the material of the cover layer can include epoxy resin and PI, or the material of the cover layer can include PE, PU, PET or other suitable materials. When the insulation layer 212 is fabricated by using the prepreg, the resin material or the ceramic material, the passivation layer 240 can be formed in the solder resist lacquer or the dry film. When the insulation layer 212 is fabricated by using the flexible material, the passivation layer 240 can be formed in the cover layer.

In addition, according to the embodiment shown by FIG. 2A, the passivation layer 240 covers a portion of the pads 214 and the conductive bump 230. However, according to different demands for the products, the passivation layer 240 may be not in contact with the conductive bumps 230, and even not in contact with the pads 214. In other words, in other embodiments not illustrated, the passivation layer 240 can completely expose the conductive bumps 230 and the pads 214.

As shown by FIG. 2A, the circuit board 200 includes two conductive bumps 230 and two barriers 220, and the circuit substrate 210 includes two pads 214; however, it should be noted that in other embodiments not illustrated, the circuit board 200 can also include only one conductive bump 230 and only one barrier 220, and the circuit substrate 210 can include only one pad 214.

Certainly, the circuit board 200 can also include over two conductive bumps 230 and over two barriers 220, and similarly, the circuit substrate 210 can also include over two pads 214. Therefore, the numbers of the conductive bump 230, the barrier 220 and the pad 214 as shown in FIG. 2A are merely illustrated as an example, and the present invention is not limited thereto.

FIG. 2B is a schematic cross-sectional view illustrating a plurality of solder bumps connected with the circuit board of FIG. 2A. Referring to FIG. 2B, the conductive bumps 230 can connect a plurality of solder bumps 202, wherein the solder bumps 202 can be solder balls, or the solder bumps 202 can have other suitable shapes. Therefore, a resistor, a capacitor, an inductor, a chip, a chip package or other electronic components can be installed onto the circuit board 200 by the solder bumps 202.

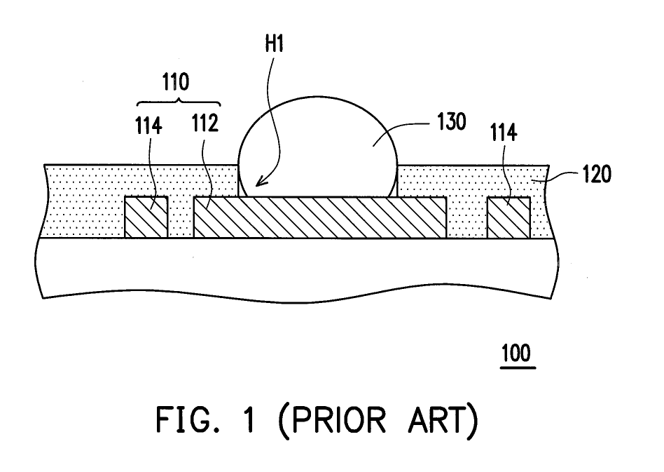

Compared with a prior art (referring to FIG. 1), the contact area between each of the conductive bumps 230 and one of the solder bumps 202 is larger, so that the adhesion between the circuit board 200 and the solder bump 202 can be enhanced, and thereby it is less likely for the solder bumps 202 to peel off from the conductive bumps 230. As a result, the above-mentioned electronic components can be installed onto the circuit board 200 more firmly, so that the product reliability of the circuit board 200 is increased.

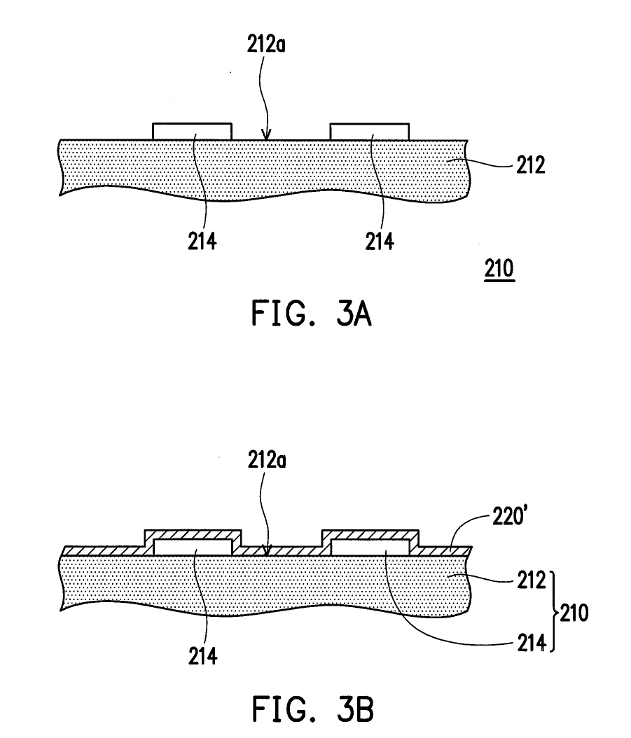

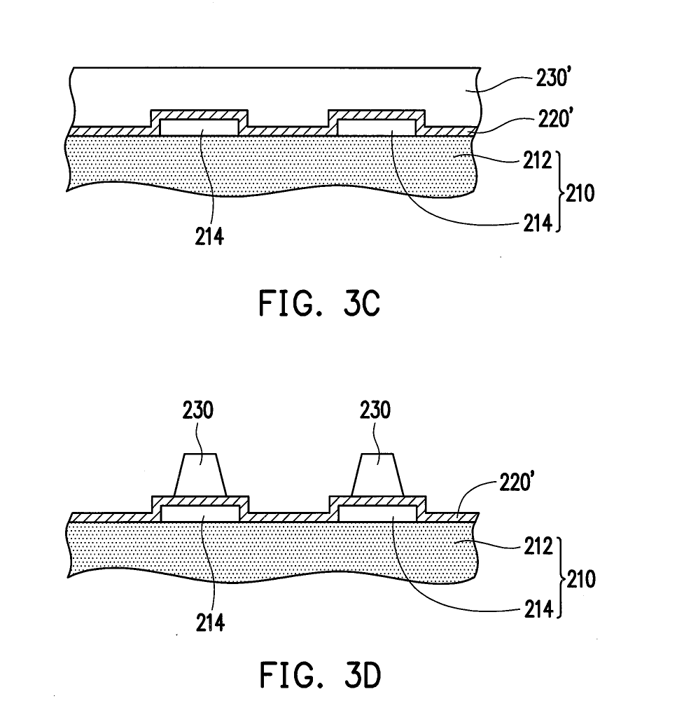

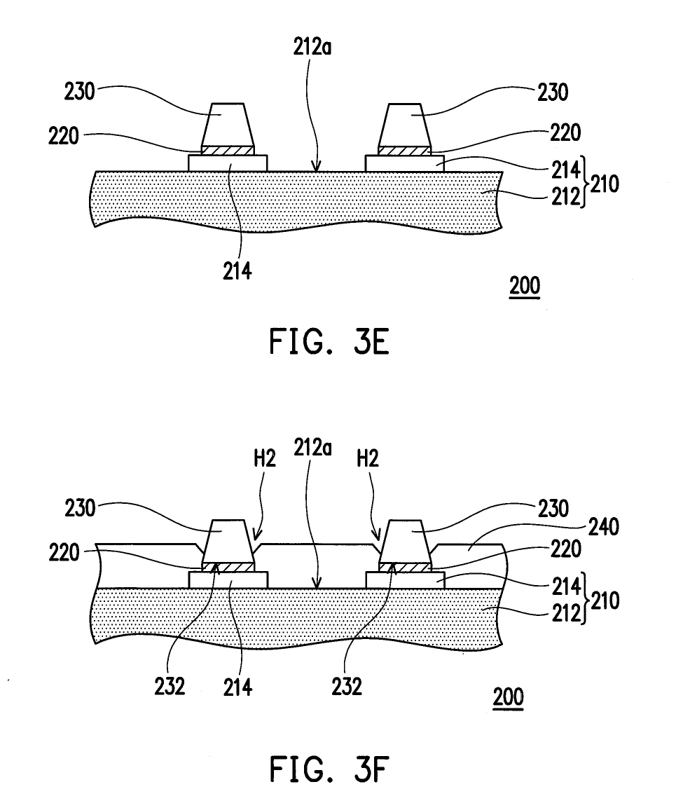

The above descriptions only introduce the structure of the circuit board 200. The following descriptions accompanied with FIGS. 3A to 3F explain the process for fabricating the circuit board 200.

FIGS. 3A to 3F are schematic views illustrating a process for fabricating the circuit board of FIG. 2A. Referring to FIG. 3A, first, the circuit substrate 210 having the insulation layer 212 and the plurality of pads 214 is provided, wherein the pads 214 are in contact with the insulation layer 212, and the pads 214 protrude from the surface 212a of the insulation layer 212.

Referring to FIG. 3B, next, a barrier material layer 220′ is then formed on the circuit substrate 210, wherein the barrier material layer 220′ completely covers the surface 212a of the insulation layer 212 and the pads 214. The material of the barrier material layer 220′ can be tin, gold, nickel, chromium, zinc, aluminum, titanium, other suitable metal material, or a combination thereof. In other words, the material of the barrier material layer 220′ can be alloy, or the material of the barrier material layer 220′ can be a multilayer film formed by at least two different metals.

In the present embodiment, forming the barrier material layer 220′ has various methods. For example, the barrier material layer 220′ can be formed by performing an electroplating process, an electroless plating, a spray coating method, or a chemical vapor deposition (CVD) process. Certainly, the barrier material layer 220′ can be formed by performing a physical vapor deposition (PVD) process, such as an evaporation deposition process or a sputtering deposition process, or can be formed by using other suitable methods.

Referring to FIGS. 3C and 3D, next, a plurality of conductive bumps 230 are then formed on the barrier material layer 220′, wherein the material of the barrier material layer 220′ is different from that of the conductive bumps 230, and the conductive bumps 230 is opposite to the pads 214. In other words, the conductive bumps 230 are corresponding to the pads 214.

Forming the conductive bumps 230 has various methods. The method of forming the conductive bumps 230 disclosed in FIGS. 3C and 3D is illustrated hereinafter as an example. However, the method of forming the conductive bumps 230 disclosed in FIGS. 3C and 3D is merely illustrated as an example, and the present invention is not limited thereto.

Referring to FIG. 3C, a conductive material layer 230′ is formed at first, wherein the conductive material layer 230′ completely covers the barrier material layer 220′. The conductive material layer 230′ can be formed by performing the electroplating process, the electroless plating process, the CVD process, the PVD process (e.g. the evaporation deposition process or the sputtering deposition process), or other suitable methods.

Referring to FIGS. 3C and 3D, the conductive material layer 230′ is then patterned to form a plurality of conductive bumps 230. The conductive material layer 230′ can be patterned by performing a photolithography process and an etching process, or other suitable methods. For example, the material of the conductive material layer 230′ can be copper or other metal materials capable of being etched by an alkaline etchant. Thereby, the conductive material layer 230′ can be patterned to form the conductive bumps 230 by using the alkaline etchant.

The barrier material layer 220′ can be fabricated by using tin, gold, nickel, chromium, zinc, aluminum, titanium, or a combination thereof The above-mentioned metal materials are characterized as being difficult to be etched by the alkaline etchant, and thereby the barrier material layer 220′ can protect the circuit substrate 210 when the conductive material layer 230′ is etched by the alkaline etchant, so that the pads 214 are protected from being damaged by the alkaline etchant.

In addition to the above-mentioned methods of forming the conductive bumps 230, using other methods can form the conductive bumps 230. For example, in other embodiments not illustrated, a patterned plating mask layer can be formed on the barrier material layer 220′ at first. Then, the conductive bumps 230 are formed on the barrier material layer 220′ partially exposed by the patterned plating mask layer by performing the electroplating process, the electroless plating process, the CVD process, the PVD process, or other suitable processes.

After that, the patterned plating mask layer is removed. Thereby, the conductive bumps 230 as shown in FIG. 3D can also be formed. In addition, using carbon paste, silver paste, or other conductive paste can form the conductive bumps 230.

Referring to FIGS. 3D and 3E, next, the conductive bumps 230 are then used as a mask for removing a portion of the barrier material layer 220′, so as to expose the surface 212a of the insulation layer 212, and to form the plurality of barriers 220 connected between the conductive bumps 230 and the pads 214. According to the present embodiment, the method of removing the portion of the barrier material layer 220′ can be performing the etching process. An acid etchant or other etchants causing almost no damages to the conductive bumps 230 and the pads 214 can be adopted in the etching process.

Thereby, the etching process can remove the portion of the barrier material layer 220′ to form the barriers 220 without affecting the conductive bumps 230 and the pads 214, and an edge of each of the barriers 220 is substantially aligned with an edge of the corresponding bottom surface 232. After the barriers 220 are formed, the fabrication of the circuit board 200 is substantially completed.

Referring to FIG. 3F, the passivation layer 240 can further be formed on the insulation layer 212 after the portion of the barrier material layer 220′ is removed. The passivation layer 240 is classified into many types. For example, the passivation layer 240 can be formed by the liquid state of solder resist, the film type of solder resist or the organic cover layer. Therefore, the method of forming the passivation layer 240 varies with different types thereof.

For example, when the passivation layer 240 is formed by the liquid state of solder resist, the passivation layer 240 can be formed by utilizing a printing or a spraying method. When the passivation layer 240 is formed by the film type of solder resist or the organic cover layer, the method of forming the passivation layer 240 can include steps as follows. First, a solder resist film or a organic cover layer is laminated, wherein the solder resist film or the organic cover layer completely covers the insulation layer 212, the pads 214, and the conductive bumps 230.

Then, the solder resist film or the organic cover layer is irradiated by a laser beam in order to fuse a portion of the solder resist film or the organic cover film for forming a plurality of openings H2 exposing the conductive bumps 230. Certainly, the openings H2 can be formed by performing the photolithography process and the etching process, wherein the etching process can be a dry etching process such as a plasma etching process, or can be a wet etching process. Furthermore, the passivation layer 240 can be a photosensitive dry film. Thereby, by using an exposure process and a development process, the openings H2 can also be formed, and the fabrication of the circuit board 200 can also be completed.

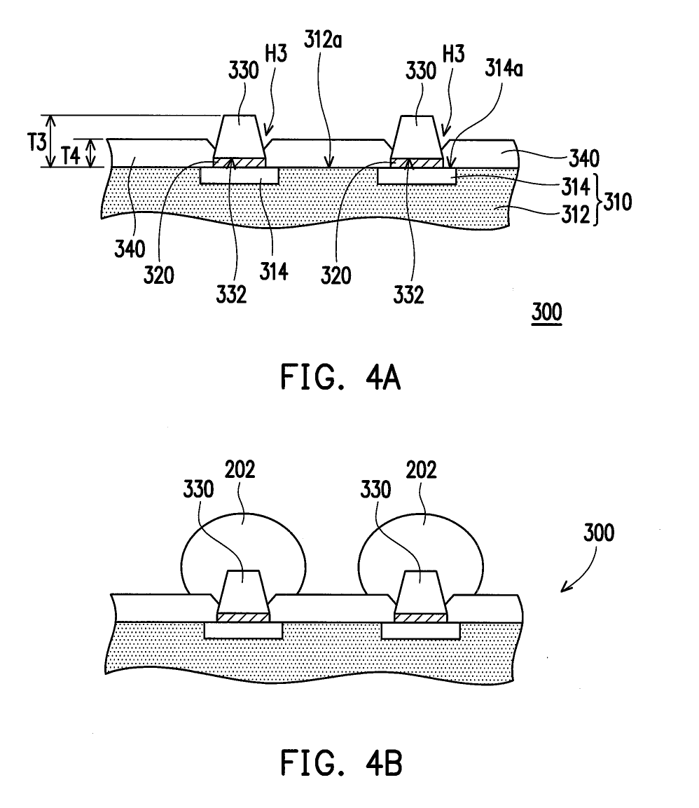

FIG. 4A is a schematic cross-sectional view of a circuit board according to another embodiment of the present invention. Referring to FIG. 4A, the circuit board 300 includes a circuit substrate 310, a plurality of barriers 320 and a plurality of conductive bumps 330. The circuit substrate 310 includes an insulation layer 312 and a plurality of pads 314. The pads 314 are in contact with the insulation layer 312. The pads 314 are disposed on a surface 312a of an insulation layer 312 and embedded in the insulation layer 312, wherein the surface 312a of the insulation layer 312 is substantially aligned with a top surface 314a of the pads 314.

Furthermore, the circuit substrate 310 can further include a plurality of traces disposed on the surface 312a (not shown in FIG. 4A), and the circuit substrate 310 can further include a plurality of conductive blind vias, a plurality of plated through holes or other inner circuit structures (not shown in FIG. 4A). The pads 314 are embedded in the insulation layer 312. Therefore, the circuit substrate 310 is substantially an embedded circuit board, and the embedded circuit board can be a single side circuit board, a double side circuit board or a multi-layer circuit board.

Accordingly, the insulation layer 312 can be fabricated by using a prepreg, a resin material, a ceramic material or a flexible material, wherein the flexible material includes PI, PE, PU, PET, or other flexible macromolecule materials. When the insulation layer 312 is fabricated by using the prepreg, the resin material or the ceramic material, the circuit substrate 310 is substantially a rigid circuit board. When the insulation layer 312 is fabricated by using the flexible material, the circuit substrate 310 is substantially a flexible circuit board.

The conductive bumps 330 are disposed upon the pads 314, while the barriers 320 are connected between the pads 314 and the conductive bumps 330. The bottom surfaces 332 of the conductive bumps 330 are opposite to the pads 314. Namely, the bottom surfaces 332 of the conductive bumps 330 are disposed corresponding to the pads 314. The barriers 320 completely cover the bottom surfaces 332 of the conductive bumps 330, and the material of the conductive bumps 330 is different from the material of the barriers 320. The materials and the shapes of the conductive bumps 330 and the barriers 320 are the same as those of the conductive bumps 230 and the barrier 220 in the above-mentioned embodiment, and therefore detailed description is not repeated.

The circuit board 300 can further include a passivation layer 340 disposed on the insulation layer 312. The passivation layer 340 has a plurality of openings H3 exposing the conductive bumps 330. The total thickness T3 of the conductive bump 330 and the barrier 320 is larger than the thickness T4 of the passivation layer 340. In other words, the conductive bumps 330 protrude from the surface of the passivation layer 340. In addition, the material of the passivation layer 340 is the same as the material of the passivation layer 240 in the above-mentioned embodiment, and therefore detailed descriptions are not repeated.

According to the embodiment shown by FIG. 4A, the passivation layer 340 covers a portion of the pads 314 and the conductive bumps 330. However, according to different demands for the products, the passivation layer 340 also may be not in contact with the conductive bumps 330, and even not in contact with the pads 314. In other words, in other embodiments not illustrated, the passivation layer 340 can completely expose the conductive bumps 330 and the pads 314.

As shown by FIG. 4A, the circuit board 300 includes two conductive bumps 330 and two barriers 320, and the circuit substrate 310 includes two pads 314; however, it should be noted that in other embodiments not illustrated, the circuit board 300 can include only one conductive bump 330 and only one barrier 320, and the circuit substrate 310 can include only one pad 314.

Furthermore, the circuit board 300 can also include at least two conductive bumps 330 and at least two barriers 320, and similarly, the circuit substrate 310 can also include at least two pads 314. Therefore, the numbers of the conductive bump 330, the barrier 320 and the pad 314 as shown in FIG. 4A are merely illustrated as an example, and the present invention is not limited thereto.

FIG. 4B is a schematic cross-sectional view illustrating a plurality of solder bumps connected with the circuit board of FIG. 4A. Referring to FIG. 4B, the conductive bumps 330 can be connected with a plurality of solder bumps 202. A resistor, a capacitor, an inductor, a chip, a chip package or other electronic components can be installed onto the circuit board 300 by means of the solder bumps 202. Compared with the prior art (referring to FIG. 1), the contact area between each of the conductive bumps 330 and any solder bump 202 is larger, and therefore the adhesion between the circuit board 300 and the solder bump 202 can be enhanced. As a result, by utilizing the present invention, the above-mentioned electronic components can be installed onto the circuit board 300 more firmly, and thereby the product reliability of the circuit board 300 can be increased.

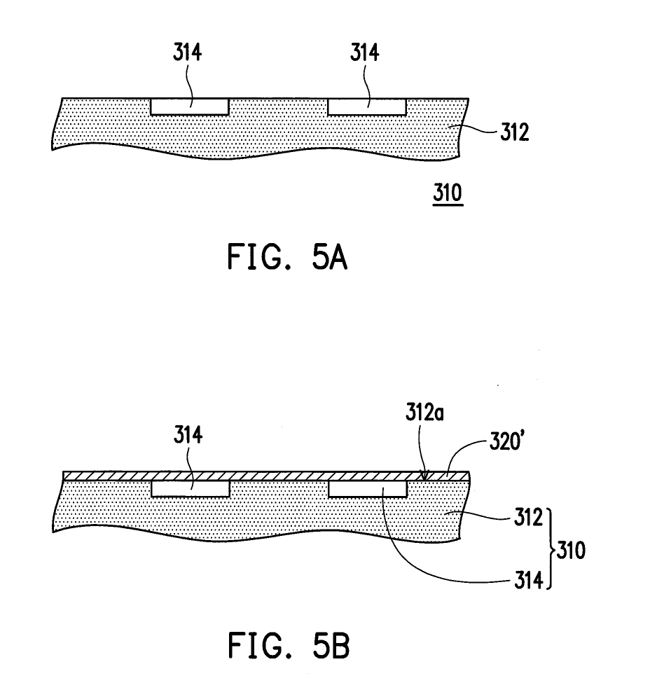

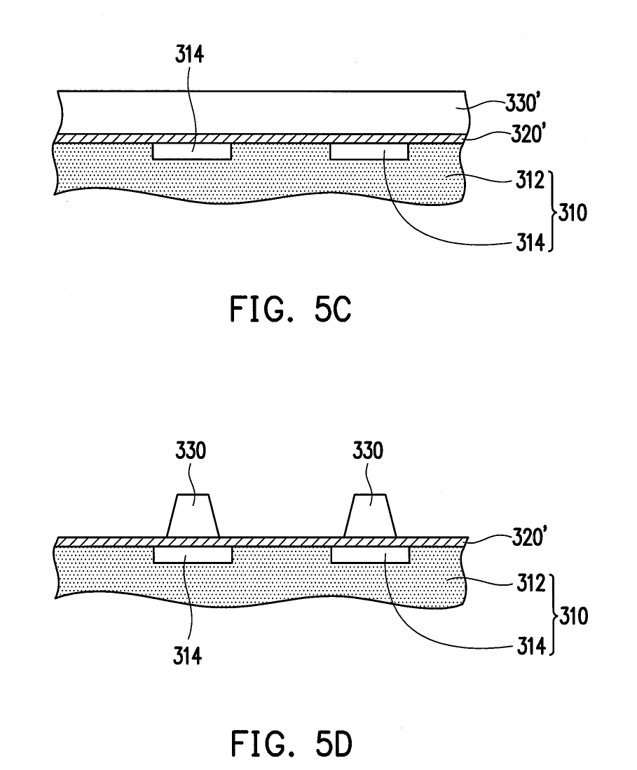

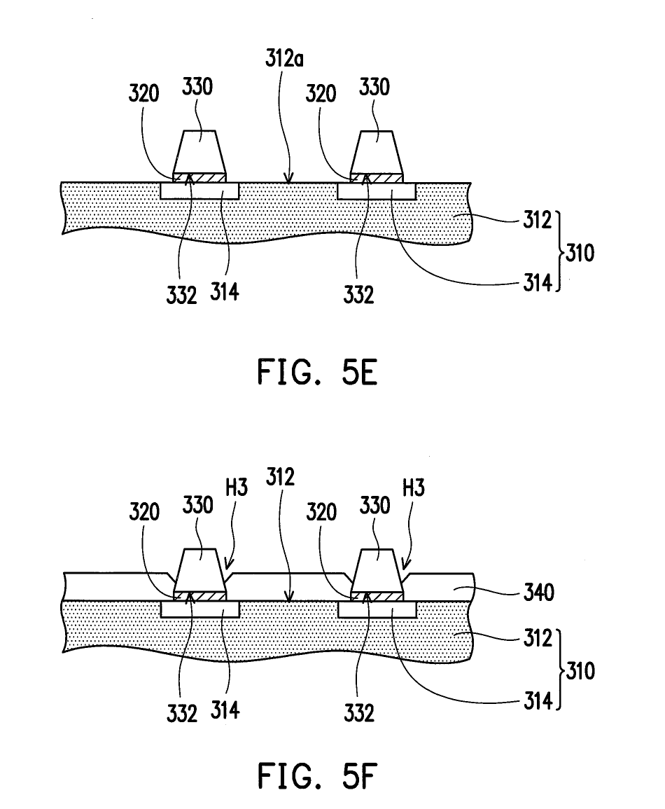

The above descriptions only introduce the structure of the circuit board 300. The following descriptions accompanied with FIGS. 5A to 5F explain the process for fabricating the circuit board 300 in detail. Because the process for fabricating the circuit board 300 of the present embodiment is similar to the process for fabricating the circuit board 200 of above-mentioned embodiment, the differences therebetween are emphasized in the following descriptions.

FIGS. 5A to 5F are schematic views illustrating a process for fabricating the circuit board as shown in FIG. 4A. Please refer to FIG. 5A and FIG. 5B in sequence. First, the circuit substrate 310 is provided. Then, a barrier material layer 320′ is formed on the circuit substrate 310; wherein the barrier material layer 320′ completely covers the surface 312a of the insulation layer 312 and the pads 314. The method of forming the barrier material layer 320′ is the same as the method of forming the barrier material layer 220′ of the above-mentioned embodiment, and therefore the detailed descriptions are not repeated.

Referring to FIGS. 5C and 5D, next, the plurality of conductive bumps 330 are then formed upon the barrier material layer 320′, wherein the material of the barrier material layer 320′ is different from the material of the conductive bumps 330, and the conductive bumps 330 are opposite to the pads 314. Namely, the conductive bumps 330 are disposed corresponding to the pads 314.

Forming the conductive bumps 330 has various methods. The method of forming the conductive bumps 330 disclosed in FIGS. 5C and 5D are illustrated hereinafter as an example. However, it should be noted that the method of forming the conductive bumps 330 disclosed in FIGS. 5C and 5D is merely illustrated as an example, and the present invention is not limited thereto.

Referring to FIG. 5C, a conductive material layer 330′ is formed at first, wherein the conductive material layer 330′ completely covers the barrier material layer 320′. The method of forming the conductive material layer 330′ is the same as the method of forming the conductive material layer 230′ of the above-mentioned embodiment, and therefore the detailed description is not repeated.

Referring to FIGS. 5C and 5D, the conductive material layer 330′ is then patterned to form the plurality of conductive bumps 330. The conductive material layer 330′ can be patterned by performing a photolithography process and an etching process, or other suitable methods. For example, the material of the conductive material layer 330′ can be copper or other metal materials capable of being etched by an alkaline etchant. Thereby, the conductive material layer 330′ can be patterned to form the conductive bumps 330 by using the alkaline etchant.

The material of the barrier material layer 320′ is the same as the material of the barrier material layer 220′ of the above-mentioned embodiment. Namely, the barrier material layer 320′ can be fabricated by using tin, gold, nickel, chromium, zinc, aluminum, titanium, or a combination thereof The above-mentioned metal materials are characterized as being difficult to be etched by the alkaline etchant, and thereby the barrier material layer 320′ can protect the circuit substrate 310 when the conductive material layer 330′ is etched by the alkaline etchant, so that the pads 314 are protected from being damaged by the alkaline etchant.

In addition to the above-mentioned methods of forming the conductive bumps 330, the conductive bumps 330 can be formed by using other methods. For example, in other embodiments not illustrated, a patterned plating mask layer can be formed on the barrier material layer 320′ at first. Then, the conductive bumps 330 are formed on the barrier material layer 320′ partially exposed by the patterned plating mask layer by performing the electroplating process, the electroless plating process, the CVD process, the PVD process, or other suitable processes.

After that, the patterned plating mask layer is removed. Therefore, the conductive bumps 330 as shown in FIG. 5D can also be formed. In addition, the conductive bumps 330 can be formed by using carbon paste, silver paste, or any other suitable conductive paste.

Referring to FIGS. 5D and 5E, next, the conductive bumps 330 are then used as a mask for removing a portion of the barrier material layer 320′, so as to expose the surface 312a of the insulation layer 312, and to form the plurality of barriers 320 connected between the conductive bumps 330 and the pads 314. According to the present embodiment, the method of removing the portion of the barrier material layer 320′ can be performing the etching process. An acid etchant or other etchants causing no damages the conductive bumps 330 and the pads 314 can be adopted in the etching process.

Thereby, the etching process can remove the portion of the barrier material layer 320′ to form the barriers 320 without affecting the conductive bumps 330 and the pads 314, and an edge of each of the barriers 320 is substantially aligned with an edge of the corresponding bottom surface 332. Until now, the fabrication of the circuit board 300 is substantially completed.

Referring to FIG. 5F, the passivation layer 340 can further be formed on the insulation layer 312 after the portion of the barrier material layer 320′ is removed. The method of forming the passivation layer 340 and the openings H3 are the same as the above-mentioned embodiment, and therefore the detailed description is omitted.

In summary, according to the present invention, the process for fabricating the circuit board may be applied to the circuit board, which the solder bumps, need to be installed onto. Moreover, the adhesion between the solder bumps and the circuit board can be enhanced, and thereby it is less likely for the solder bumps to peel off from the circuit board. As a result, by utilizing the present invention, the electronic components can be installed onto the circuit board more firmly, so as to improve the product reliability of the circuit board.

Also, when at least one conductive bump is formed on the conductive material layer by performing the etching process, the pads are protected from being damaged by etchants such as the alkaline etchant because the barrier material layer with a material different from the conductive bumps can effectively protect the circuit substrate. Accordingly, the production yield of the circuit board can be increased by utilizing the present invention.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A process for fabricating a circuit board, comprising:
providing a circuit substrate including an insulation layer and at least one pad in contact with the insulation layer;
forming a barrier material layer on the circuit substrate, wherein the barrier material layer completely covers a surface of the insulation layer and the pad;
forming at least one conductive bump on the barrier material layer, wherein the conductive bump is opposite to the pad, and the material of the barrier material layer is different from the material of the conductive bump; and
removing a portion of the barrier material layer by using the conductive bump as a mask, so as to expose the surface of the insulation layer and to form a barrier connected between the conductive bump and the pad.

2. The process for fabricating the circuit board according to claim 1, wherein the pad protrudes from the surface of the insulation layer.

3. The process for fabricating the circuit board according to claim 2, further comprising forming a passivation layer on the insulation layer after removing the portion of the barrier material layer, wherein the passivation layer has at least one opening exposing the conductive bump, and the total thickness of the conductive bump, the pad and the barrier is larger than the thickness of the passivation layer.

4. The process for fabricating the circuit board according to claim 1, wherein the pad is embedded in the insulation layer, and the surface of the insulation layer is substantially aligned with a top surface of the pad.

5. The process for fabricating the circuit board according to claim 4, further comprising forming a passivation layer on the insulation layer after removing the portion of the barrier material layer, wherein the passivation layer has at least one opening exposing the conductive bump, and the total thickness of the conductive bump and the barrier is larger than the thickness of the passivation layer.

6. The process for fabricating the circuit board according to claim 1, wherein a method of forming the conductive bump comprises:
forming a conductive material layer, wherein the conductive material layer completely covers the barrier material layer; and
patterning the conductive material layer.

7. The process for fabricating the circuit board according to claim 1, wherein the material of the barrier material layer is selected from a group consisting of tin, gold, nickel, chromium, zinc, aluminum, and titanium.

8. The process for fabricating the circuit board according to claim 1, wherein the insulation layer is fabricated by using a prepreg, a resin material, a ceramic material or a flexible material.

9. The process for fabricating the circuit board according to claim 8, wherein the flexible material comprises polyimide, polyester, polyurethane or polyethylene terephthalate.
